(19) United States
(12) Patent Application Publication
(10) Pub. No.: US 2012/0241899 A1
(43) Pub. Date: Sep. 27, 2012

(54) POWER SEMICONDUCTOR DEVICE

(75) Inventor: Masakazu KOBAYASHI, Hyogo-ken (JP)

(73) Assignee: Kabushiki Kaisha Toshiba, Tokyo (JP)

(21) Appl. No.: 13/423,131

(22) Filed: Mar. 16, 2012

(30) Foreign Application Priority Data
Mar. 24, 2011 (JP) 2011-066652

(51) Int. Cl. H01L 29/06

(52) U.S. Cl. 257/487; 257/E29.012

(57) ABSTRACT

A power semiconductor device includes a first semiconductor layer of a first conductivity type, a second semiconductor layer of the first conductivity type, a third semiconductor layer of a second conductivity type, and a fourth semiconductor layer of the second conductivity type. The second semiconductor layer is provided on the first semiconductor layer and has a lower concentration of first conductivity type impurity than the first semiconductor layer. The third semiconductor layer is provided on a surface of the second semiconductor layer. The fourth semiconductor layer is selectively provided on a surface of the third semiconductor layer and has a higher concentration of second conductivity type impurity than the third semiconductor layer. The third semiconductor layer includes a carrier lifetime reducing region adjacent to a bottom surface of the fourth semiconductor layer. The carrier lifetime reducing region is spaced from the second semiconductor layer.

### CROSS-REFERENCE TO RELATED APPLICATION

This application is based upon and claims the benefit of priority from the prior Japanese Patent Application No. 2011-066652, filed on Mar. 24, 2011; the entire contents of which are incorporated herein by reference.

### FIELD

Embodiments described herein relate generally to a power semiconductor device with improved reverse recovery characteristics.

### BACKGROUND

Power semiconductor devices including at least partly a diode structure such as FRD (fast recovery diode), MOSFET (metal oxide semiconductor field effect transistor), and IGBT (insulated gate bipolar transistor) are used as switching elements in a power supply circuit. In order to enable fast switching and to reduce switching loss, such power semiconductor devices are required to have short reverse recovery time. In order to reduce reverse recovery time, it is necessary to use a semiconductor layer having low p-type or n-type impurity concentration to reduce the supply amount of holes or electrons when the diode is forward biased. On the other hand, in order to reduce each contact resistance with the anode electrode and the cathode electrode, the p-type or n-type impurity concentration of the semiconductor layer needs to be set high at the junction with these electrodes, respectively. However, this causes the problem of increasing the reverse recovery time of the diode.

### BRIEF DESCRIPTION OF THE DRAWINGS

FIG. 1 is a main part sectional view of a power semiconductor device according to a first embodiment in a device region where a diode structure is formed and a current flows.

FIG. 2 is a hole concentration profile in the depth direction of the power semiconductor device according to the first embodiment.

FIG. 3 is the voltage-current characteristic of the power semiconductor device according to the first embodiment.

FIG. 4 is a main part sectional view of a power semiconductor device according to a second embodiment.

FIG. 5 is a main part sectional view of a power semiconductor device according to a third embodiment.

### DETAILED DESCRIPTION

A power semiconductor device includes a first semiconductor layer of a first conductivity type, a second semiconductor layer of the first conductivity type, a third semiconductor layer of a second conductivity type, a fourth semiconductor layer of the second conductivity type, a first main electrode, and a second main electrode. The second semiconductor layer of the first conductivity type is provided on the first semiconductor layer and has a lower concentration of first conductivity type impurity than the first semiconductor layer. The third semiconductor layer of the second conductivity type is provided on a surface of the second semiconductor layer on opposite side from the first semiconductor layer. The fourth semiconductor layer of the second conductivity type is selectively provided on a surface of the third semiconductor layer on opposite side from the first semiconductor layer and has a higher concentration of second conductivity type impurity than the third semiconductor layer. The first main electrode is electrically connected to the first semiconductor layer. The second main electrode is electrically connected to the fourth semiconductor layer. The third semiconductor layer includes a carrier lifetime reducing region adjacent to a bottom surface of the fourth semiconductor layer on the first semiconductor layer side. The carrier lifetime reducing region is spaced from the second semiconductor layer.

Embodiments of the invention will now be described with reference to the drawings. The drawings used to describe the embodiments are schematic for simplicity of description. The shape, dimension, size relation and the like of the components in the drawings do not necessarily need to be realized as shown in actual practice, but can be suitably modified as long as the effect of the invention is achieved. As a semiconductor material, silicon is taken as an example in this description. The first conductivity type and the second conductivity type are n-type and p-type, respectively, in this description. In the case where n⁻-type, n-type, and n⁺-type are used, it is assumed that the impurity concentrations thereof have the relation n⁻<n<n⁺. The same also applies to p⁻-type, p-type, and p⁺-type. In the description of the embodiments, a diode is taken as an example of the power semiconductor device. However, these embodiments are also similarly applicable to MOSFET, IGBT, and other insulated gate semiconductor devices including a diode structure.

### First Embodiment

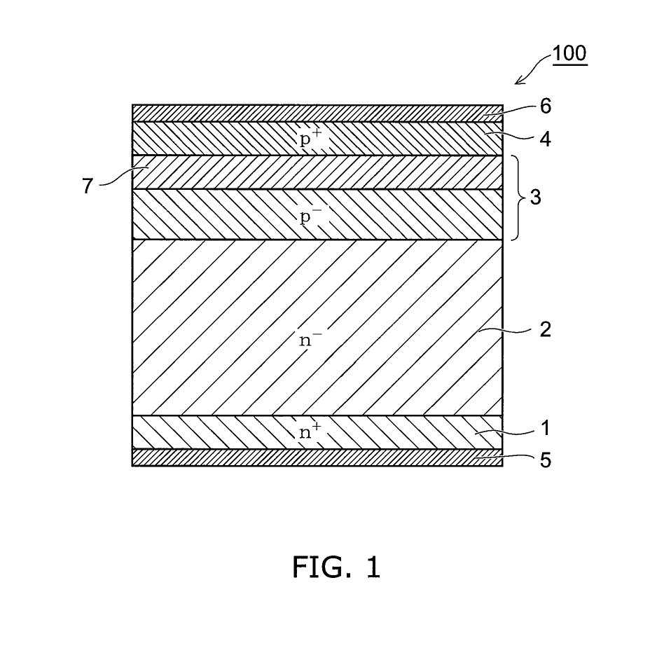

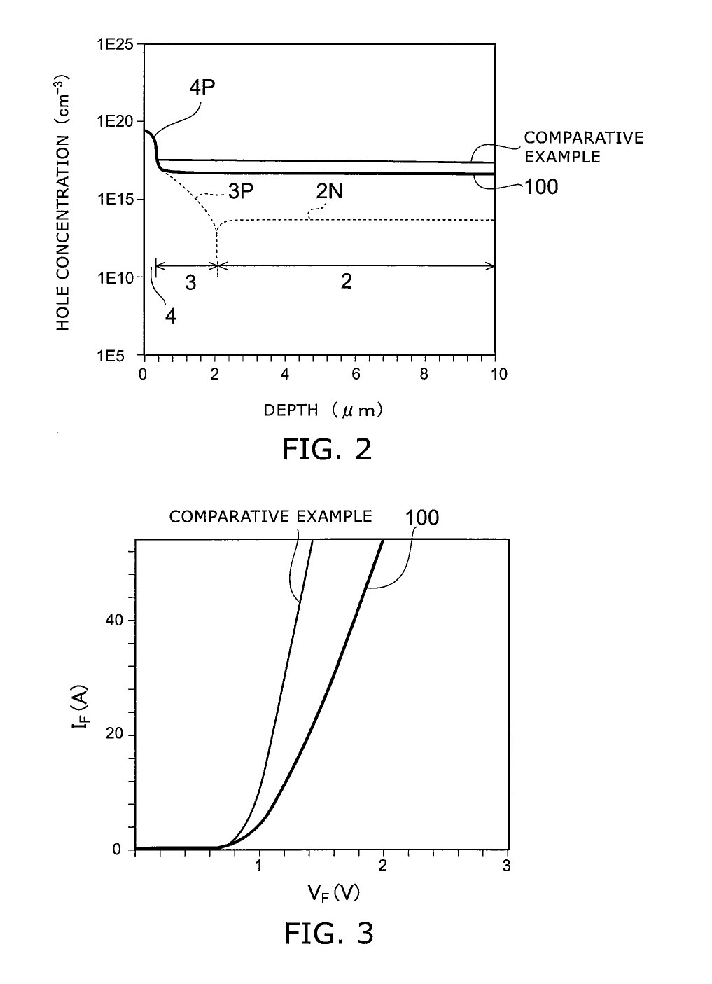

With reference to FIGS. 1 to 3, a power semiconductor device according to a first embodiment of the invention is described. FIG. 1 shows a main part sectional view of the power semiconductor device according to the first embodiment in the device region where a diode structure is formed and the current flows. FIG. 2 shows a hole concentration profile in the depth direction of the power semiconductor device according to the first embodiment. FIG. 3 shows the voltage-current characteristic of the power semiconductor device according to the first embodiment. The power semiconductor device according to the first embodiment is described with FRD taken as an example. In the description of the semiconductor layer, silicon is taken as an example. Here, the p-type impurity concentration, for instance, refers to the actual concentration of p-type impurity contained in the semiconductor layer. The net p-type impurity concentration refers to the concentration after being compensated with the n-type impurity contained in the semiconductor layer. The same also applies to the n-type impurity concentration and the net n-type impurity concentration.

As shown in FIG. 1, the FRD 100 as a power semiconductor device according to the first embodiment includes an n⁺-type (first conductivity type) semiconductor layer (first semiconductor layer) 1, an n⁻-type semiconductor layer (second semiconductor layer) 2, a p⁻-type (second conductivity type) semiconductor layer (third semiconductor layer) 3, a p⁺-type semiconductor layer (fourth semiconductor layer) 4, a cathode electrode (first main electrode) 5, and an anode (second main electrode) 6. The n⁻-type semiconductor layer 2 is provided on the n⁺-type semiconductor layer 1 and includes n-type impurity at a concentration lower than the concentration of n-type impurity of the n⁺-type semiconductor layer 1. The n⁻-type semiconductor layer 2 can be formed by e.g. epitaxial growth on the n⁺-type semiconductor layer 1.

The p⁻-type semiconductor layer 3 is selectively provided on the surface of the n⁻-type semiconductor layer 2. The p⁻-type semiconductor layer 3 can be formed by e.g. performing ion implantation of p-type impurity (e.g., boron) into the surface of the n⁻-type semiconductor layer 2 and then diffusing the p-type impurity by heat treatment. The FRD 100 includes a device region and a termination region externally surrounding the device region in the n⁻-type semiconductor layer 2. At the outer peripheral edge of the termination region, the FRD 100 includes a dicing line along which the semiconductor chip is cut off. FIG. 1 shows part of the device region where a diode is formed and the current flows in the stacking direction. Outside this device region, the termination region (not shown) is formed, where the current does not flow in the stacking direction. The p⁻-type semiconductor layer 3 includes p-type impurity. As a result of compensation with the n-type impurity of the n⁻-type semiconductor layer 2, the p⁻-type semiconductor layer 3 becomes a p-type semiconductor. The p-type impurity concentration of the p⁻-type semiconductor layer 3 is set by the ion implantation of p-type impurity so that the net p-type impurity concentration after compensation of the p⁻-type semiconductor layer 3 is made higher than the net n-type impurity concentration of the n⁻-type semiconductor layer 2.

The p⁺-type semiconductor layer 4 is provided on the surface of the p⁻-type semiconductor layer 3. Like the foregoing, the p⁺-type semiconductor layer 4 is also formed by ion implantation of p-type impurity and heat treatment. The ion implantation of p-type impurity is performed so that the p⁺-type semiconductor layer 4 has a p-type impurity concentration higher than the p-type impurity concentration of the p⁻-type semiconductor layer 3.

Here, the p⁻-type semiconductor layer 3 includes a carrier lifetime reducing region 7 treated so as to reduce carrier lifetime. The carrier lifetime reducing region 7 is provided adjacent to the bottom surface of the p⁺-type semiconductor layer 4 on the n⁺-type semiconductor layer 1 side, and spaced from the n⁻-type semiconductor layer 2. This treatment for reducing carrier lifetime is e.g. a treatment for generating defects in a semiconductor layer by implanting protons or helium ions into the semiconductor layer. Because of the defects generated in the semiconductor layer, the semiconductor layer comes to include recombination levels (levels formed between the conduction band and the valence band) in the forbidden band. Such recombination levels facilitate recombination between electrons in the conduction band and holes in the valence band. Thus, the lifetime of carriers (electrons and holes) is reduced. Hence, in the carrier lifetime reducing region 7, the carrier lifetime is made shorter than the carrier lifetime in the p⁻-type semiconductor layer 3 before the aforementioned treatment. In other words, the carrier lifetime reducing region 7 has a higher crystal defect density than the portion of the p⁻-type semiconductor layer 3 except the carrier lifetime reducing region 7. Hence, the carrier lifetime reducing region 7 has a shorter carrier lifetime. By adjusting the density of crystal defects by the implantation amount of protons or helium ions, the duration of the carrier lifetime can be adjusted. As the defect density becomes higher, the carrier lifetime becomes shorter. As the means for generating crystal defects, the implantation of protons or helium ions can be replaced by e.g. injecting a heavy metal such as platinum, gold, or silver into the semiconductor layer. Alternatively, electron irradiation can also be used to generate defects in the crystal.

The cathode electrode 5 is electrically connected to the n⁺-type semiconductor layer 1. The anode electrode 6 is electrically connected to the p⁺-type semiconductor layer 4. The cathode electrode 5 and the anode electrode 6 need at least to be made of a metal material having high conductivity, such as aluminum and copper.

Next, the operation of the FRD 100 according to this embodiment is described. When a positive voltage with reference to the cathode electrode 5 is applied to the anode electrode 6 (forward bias), holes are supplied from the anode electrode 6 through the p⁺-type semiconductor layer 4, the p⁻-type semiconductor layer 3, and the n⁻-type semiconductor layer 2 to the cathode electrode 5. From the cathode electrode 5, electrons are supplied through the n⁺-type semiconductor layer 1, the n⁻-type semiconductor layer 2, the p⁻-type semiconductor layer 3, and the p⁺-type semiconductor layer 4 to the anode electrode 6. As a result, electrons and holes are accumulated in the n⁻-type semiconductor layer 2 and the p⁻-type semiconductor layer 3 to produce a low resistance state (on-state). Thus, a current flows from the anode electrode 6 to the cathode electrode 5.

FIG. 2 shows, by dashed lines, the depth-direction profile of the p-type impurity concentration 4P of the p⁺-type semiconductor layer 4, the p-type impurity concentration 3P of the p⁻-type semiconductor layer 3, and the n-type impurity concentration 2N of the n⁻-type semiconductor layer 2 in the FRD 100 in the on-state. This figure shows a simulation result of the depth-direction profile of the hole concentration for these impurity concentrations. Here, as a comparative example, an FRD is considered, which is different from the FRD 100 according to this embodiment in lacking the carrier lifetime reducing region. FIG. 2 also shows a simulation result of the depth-direction profile of the hole concentration for the FRD of the comparative example.

The p-type impurity concentration of the FRD 100 is highest at the surface of the p⁺-type semiconductor layer 4. The p-type impurity concentration steeply decreases at the interface from the p⁺-type semiconductor layer 4 to the p⁻-type semiconductor layer 3. The p-type impurity concentration decreases again in the p⁻-type semiconductor layer 3 toward the interface between the p⁻-type semiconductor layer 3 and the n⁻-type semiconductor layer 2. Then, the p-type impurity concentration reaches the measurement limit. The n-type impurity concentration in the n⁻-type semiconductor layer 2 is distributed at a nearly constant concentration in the depth direction. The n-type impurity concentration has a value lower than the p-type impurity concentration of the p⁻-type semiconductor layer 3. In the hole concentration profile of the FRD 100, the hole concentration is nearly equal to the p-type impurity concentration in the p⁺-type semiconductor layer 4. Thus, the hole concentration profile of the FRD 100 has the same concentration profile in the depth direction as the p⁺-type semiconductor layer 4. In the p⁻-type semiconductor layer 3 and the n⁻-type semiconductor layer 2, the hole concentration profile of the FRD 100 has a constant concentration in the depth direction, and has a concentration higher than the p-type impurity concentration in the p⁻-type semiconductor layer 3.

As shown in FIG. 2, the hole concentration profile in the depth direction of the FRD of the comparative example is also a depth-direction profile similar to the hole concentration profile of the FRD according to this embodiment. However, in the hole concentration profile of the FRD 100 according to this embodiment, the hole concentration in the p⁻-type semiconductor layer 3 and the n⁻-type semiconductor layer 2 is lower than in the FRD of the comparative example. The reason for this is as follows. The FRD 100 according to this embodiment includes a carrier lifetime reducing region 7 in the p⁻-type semiconductor layer 3. The carrier lifetime reducing region 7 is adjacent to the bottom surface of the p⁺-type semiconductor layer 4 on the n⁺-type semiconductor layer 1 side. Thus, in the on-state, holes supplied from the p⁺-type semiconductor layer 4 to the p⁻-type semiconductor layer 3 are eliminated in the carrier lifetime reducing region 7. The amount of holes eliminated in the carrier lifetime reducing region 7 is larger as the carrier lifetime of the carrier lifetime reducing region 7 becomes shorter. The carrier lifetime is shorter as the density of crystal defects generated by the aforementioned treatment in the carrier lifetime reducing region 7 becomes higher.

As described above, in the FRD 100 according to this embodiment, as shown in FIG. 2, the hole concentration in the p⁻-type semiconductor layer 3 and the n⁻-type semiconductor layer 2 in the on-state is low. Thus, as shown by the forward voltage-current characteristic (V_{F}-I_{F} characteristic) in FIG. 3, the operating voltage is higher than in the comparative example. However, because of this, in the FRD 100 according to this embodiment, the hole concentration determining the reverse current during reverse recovery is lower than in the comparative example. Thus, the reverse recovery characteristic is improved. Furthermore, in the FRD 100 according to this embodiment, the operating voltage is higher than in the comparative example. However, the p⁺-type semiconductor layer 4 is provided between the p⁻-type semiconductor layer 3 and the anode electrode 6. Thus, the ohmic contact with the anode electrode 6 is originally low. Hence, the aforementioned voltage increase is acceptable.

The carrier lifetime reducing region 7 is provided in the upper end portion of the p⁻-type semiconductor layer 3. Thus, during reverse bias (off-state), the depletion layer extending into the p⁻-type semiconductor layer 3 from the junction between the p⁻-type semiconductor layer 3 and the n⁻-type semiconductor layer 2 can be prevented from reaching the carrier lifetime reducing region 7. The p-type impurity concentration (or the net p-type impurity concentration) and the thickness of the p⁻-type semiconductor layer 3 can be set so that the depletion layer does not reach the carrier lifetime reducing region 7 under application of the rated voltage of the reverse voltage of the FRD 100 according to this embodiment. If the depletion layer reaches the carrier lifetime reducing region 7 during reverse bias, a leakage current flows via recombination levels resulting from crystal defects in the carrier lifetime reducing region 7. By preventing the depletion layer from reaching the carrier lifetime reducing region 7, the leakage current during reverse bias of the FRD 100 is suppressed.

As described above, the FRD 100 according to this embodiment includes a carrier lifetime reducing region 7 in the p⁻-type semiconductor layer 3. The carrier lifetime reducing region 7 is adjacent to the bottom surface of the p⁺-type semiconductor layer 4 on the n⁺-type semiconductor layer 1 side. Thus, the FRD 100 according to this embodiment is superior in the reverse recovery characteristic, low in forward voltage, and small in reverse current.

### Second Embodiment

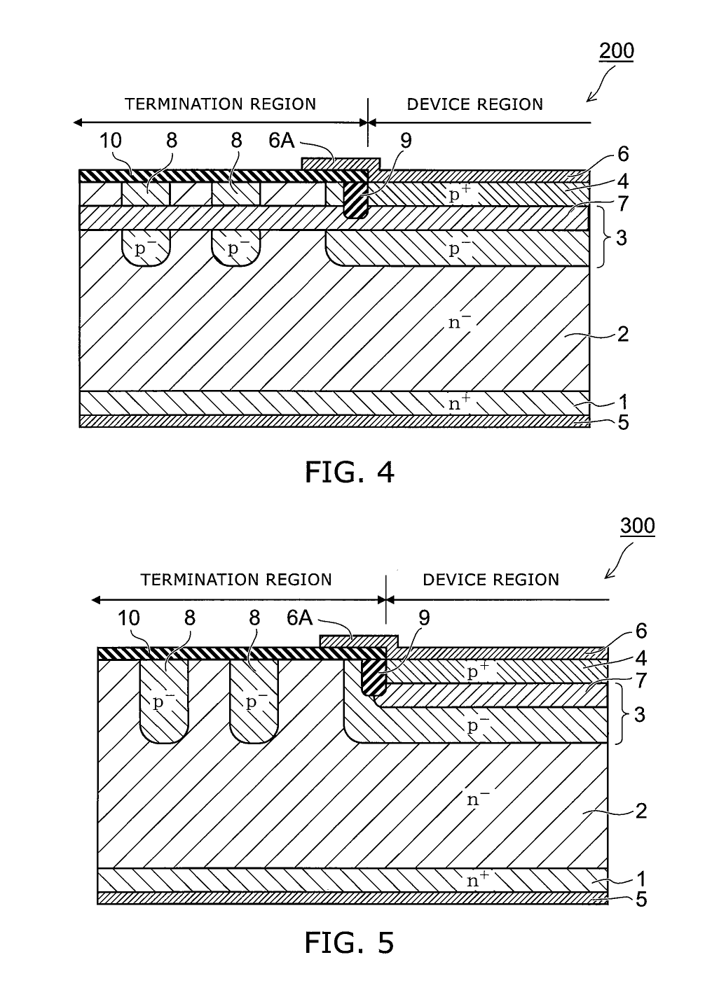

A power semiconductor device according to a second embodiment is described with reference to FIG. 4. FIG. 4 is a main part sectional view of the power semiconductor device according to the second embodiment. The portions having the same configuration as those described in the first embodiment are labeled with like reference numerals or symbols, and the description thereof is omitted. Differences from the semiconductor device according to the first embodiment are primarily described.

The power semiconductor device according to this embodiment has a structure similar to that of the FRD 100 according to the first embodiment, and is characterized as follows in the termination region. As shown in FIG. 4, the FRD 200 according to this embodiment includes a p⁻-type semiconductor layer 3 on the surface of the n⁻-type semiconductor layer 2 from the boundary between the termination region and the device region into the device region. On the surface of the p⁻-type semiconductor layer 3, a p⁺-type semiconductor layer 4 is selectively formed. The outer peripheral portion of the p⁺-type semiconductor layer 4 is spaced inward from the outer peripheral portion of the p⁻-type semiconductor layer 3. The p⁺-type semiconductor layer 4 is formed in the device region, and not formed in the termination region.

A plurality of p⁻-type guard ring layers 8 are provided. The p⁻-type guard ring layer 8 extends in the n⁻-type semiconductor layer 2 from the surface of the n⁻-type semiconductor layer 2 in the termination region toward the n⁺-type semiconductor layer 1. The p⁻-type guard ring layer 8 has a ring-shaped structure surrounding the p⁻-type semiconductor layer 3. In this embodiment, the p-type impurity concentration of the p⁻-type guard ring layer 8 and its depth extending from the surface of the n⁻-type semiconductor layer 2 toward the n⁺-type semiconductor layer 1 are made substantially the same as those of the p⁻-type semiconductor layer 3. However, these may be appropriately selected depending on the design of the breakdown voltage of the termination region of the FRD 200.

The carrier lifetime reducing region 7 is formed so as to extend not only in the device region but also to the termination region and to reach the end portion of the termination region. The regions of the n⁻-type semiconductor layer 2 and the p⁻-type semiconductor layer 3 where the carrier lifetime reducing region 7 extends have a shorter carrier lifetime than the other region.

An insulating film 9 is formed so as to have a ring-shaped structure adjacent to the outer periphery of the p⁺-type semiconductor layer 4. The insulating film 9 extends from the surface of the p⁺-type semiconductor layer 4 (the surface of the p⁺-type semiconductor layer on the opposite side from the n⁺-type semiconductor layer 1) into the p⁻-type semiconductor layer 3 and surrounds the outer periphery of the p⁺-type semiconductor layer 4. Although the insulating film 9 extends into the carrier lifetime reducing region 7 in the p⁻-type semiconductor layer 3 in this embodiment, the insulating film 9 may be formed more deeply beyond the carrier lifetime reducing region 7. However, as the insulating film 9 is provided more deeply, electric field concentration is more likely to occur in the tip portion. Hence, preferably, the insulating film 9 is extended to a depth not beyond the carrier lifetime reducing region 7. The insulating film 9 needs at least to be made of an insulator. For instance, a silicon oxide film or silicon nitride film is used for the insulating film 9. However, polyimide, for instance, can also be used.

An interlayer insulating film 10 is formed from the aforementioned insulating film 9 to the end portion of the termination region so as to cover the surface of the insulating film 9, the p⁻-type semiconductor layer 3, the n⁻-type semiconductor layer 2, and the p⁻-type guard ring layers 8. The interlayer insulating film 10 insulates the p⁻-type semiconductor layer 3, the n⁻-type semiconductor layer 2, and the p⁻-type guard ring layers 8 from outside in the termination region. The interlayer insulating film 10 can be a silicon oxide film, a silicon nitride film, or a stacked structure thereof.

An anode electrode 6 is formed so as to be electrically connected to the surface of the p⁺-type semiconductor layer 4 on the opposite side from the n⁺-type semiconductor layer 1. The anode electrode 6 includes a field plate 6A extending on interlayer insulating film 10. The field plate 6A extends from the boundary between the device region and the termination region toward the outside of the termination region. The field plate 6A extends to between the p⁻-type semiconductor layer 3 and the p⁻-type guard ring layer 8. A cathode electrode 5 is formed so as to be electrically connected to the n⁺-type semiconductor layer 1.

In the FRD 200 according to this embodiment, the device region has the same structure as that of the first embodiment. Hence, the same effect as that of the FRD 100 according to the first embodiment is achieved. Furthermore, the FRD 200 according to this embodiment includes the insulating film 9. This suppresses that, in the on-state, holes horizontally flows from the anode electrode 6 through the surface of the p⁺-type semiconductor layer 4, the p⁻-type semiconductor layer 3, and the n⁻-type semiconductor layer 2 and are supplied to the termination region. Thus, during reverse recovery, in the termination region, holes accumulated in the on-state immediately below the interlayer insulating film 10 in the n⁻-type semiconductor layer 2 are decreased. Furthermore, the path extending from the termination region and horizontally passing through the surface of the n⁻-type semiconductor layer 2, the p⁻-type semiconductor layer 3, and the p⁺-type semiconductor layer 4 to the anode electrode 6 is blocked by the insulating film 9. Because of the foregoing, the reverse recovery current flowing from the termination region to the device region is reduced. Thus, the reverse recovery characteristic of the FRD 200 is improved.

### Third Embodiment

A power semiconductor device according to a third embodiment is described with reference to FIG. 5. FIG. 5 is a main part sectional view of the power semiconductor device according to the third embodiment. The portions having the same configuration as those described in the second embodiment are labeled with like reference numerals or symbols, and the description thereof is omitted. Differences from the semiconductor device according to the second embodiment are primarily described.

The FRD 300 according to this embodiment has a structure similar to that of the FRD 200 according to the second embodiment. As shown in FIG. 5, the FRD 300 according to this embodiment is different from the FRD 200 according to the second embodiment in that the carrier lifetime reducing region 7 does not extend to the outer peripheral end portion of the termination region, but is stopped in the p⁻-type semiconductor layer 3. In the FRD 300, in the termination region, holes are horizontally supplied from the anode electrode 6 along the surface of the p⁺-type semiconductor layer 4, the p⁻-type semiconductor layer 3, and the n⁻-type semiconductor layer 2. The holes flow in the stacking direction in the n⁻-type semiconductor layer and are supplied to the cathode electrode 5. Here, unlike the FRD 200 according to the second embodiment, the carrier lifetime reducing region 7 does not exist in the termination region. Hence, the aforementioned holes horizontally supplied from the anode electrode 6 toward the termination region are supplied into the n⁻-type semiconductor layer 2 without elimination. Thus, in the FRD 300 according to this embodiment, the amount of holes present in the n⁻-type semiconductor layer 2 in the termination region are larger than in the FRD 200 according to the second embodiment. Hence, in the FRD 300 according to this embodiment, the aforementioned effect of the insulating film 9 is achieved more significantly than in the FRD 200 according to the second embodiment. Besides the foregoing, in the FRD 300 according to this embodiment, the structure of the device region is similar to that in the FRD 200 according to the second embodiment. Hence, an effect similar to that of the second embodiment is achieved.

The foregoing description is focused on the hole concentration because the reverse recovery characteristic is determined by the behavior of holes, which have low mobility. Although less effective than for holes, the same also applies to electrons. Thus, in the above embodiments, a carrier lifetime reducing region 7 can be further provided in a region of the n⁻-type semiconductor layer 2 adjacent to the n⁺-type semiconductor layer 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device comprising:
a first semiconductor layer of a first conductivity type;
a second semiconductor layer of the first conductivity type provided on the first semiconductor layer and having a lower concentration of first conductivity type impurity than the first semiconductor layer;
a third semiconductor layer of a second conductivity type provided on a surface of the second semiconductor layer on opposite side from the first semiconductor layer;
a fourth semiconductor layer of the second conductivity type selectively provided on a surface of the third semiconductor layer on opposite, side from the first semiconductor layer and having a higher concentration of second conductivity type impurity than the third semiconductor layer;
a first main electrode electrically connected to the first semiconductor layer; and
a second main electrode electrically connected to the fourth semiconductor layer,
the third semiconductor layer including a carrier lifetime reducing region adjacent to a bottom surface of the fourth semiconductor layer on the first semiconductor layer side, the carrier lifetime reducing region being spaced from the second semiconductor layer.

2. The device according to claim 1, wherein the carrier lifetime reducing region has a higher crystal defect density than a portion of the third semiconductor layer except the carrier lifetime reducing region.

3. The device according to claim 1, wherein the carrier lifetime reducing region includes a hydrogen atom or helium atom.

4. The device according to claim 1, wherein the carrier lifetime reducing region includes one of platinum, gold, and silver.

5. The device according to claim 1, wherein net second conductivity type impurity concentration of the third semiconductor layer is higher than net first conductivity type impurity concentration of the second semiconductor layer.

6. The device according to claim 1, wherein net second conductivity type impurity concentration of the third semiconductor layer is set so that a depletion layer extending from a junction between the third semiconductor layer and the second semiconductor layer toward the third semiconductor layer does not reach the carrier lifetime reducing region when a rated reverse voltage is applied between the first semiconductor layer and the fourth semiconductor layer.

7. The device according to claim 1, wherein
the third semiconductor layer is selectively formed on the surface of the second semiconductor layer,
the fourth semiconductor layer is selectively formed on the surface of the third semiconductor layer, and
the device further comprises an insulating film of a ring-shaped structure being adjacent to an outer periphery of the fourth semiconductor layer, extending from a surface of the fourth semiconductor layer on opposite side from the first semiconductor layer into the third semiconductor layer, and surrounding the outer periphery of the fourth semiconductor layer.

8. The device according to claim 7, wherein the insulating film extends from the surface of the fourth semiconductor layer into the carrier lifetime reducing region of the third semiconductor layer.

9. The device according to claim 7, wherein in a plane including the surface of the fourth semiconductor layer, the insulating film is located between the third semiconductor layer and the fourth semiconductor layer.

10. The device according to claim 7, further comprising:
an interlayer insulating film formed on a surface of the insulating film, the third semiconductor layer, and the second semiconductor layer.

11. The device according to claim 10, further comprising:
a plurality of guard ring layers of the second conductivity type extending from the surface of the second semiconductor layer into the second semiconductor layer and having an upper end connected to the interlayer insulating film.

12. The device according to claim 11, wherein the carrier lifetime reducing region extends in a plane parallel to the surface of the second semiconductor layer and is orthogonal to the plurality of guard ring layers.

13. The device according to claim 12, wherein second conductivity type impurity concentration of the plurality of guard ring layers is equal to second conductivity type impurity concentration of the third semiconductor layer.

14. The device according to claim 12, wherein the plurality of guard ring layers extend in the second semiconductor layer toward the first semiconductor layer to a same depth as bottom of the third semiconductor layer.

15. The device according to claim 10, wherein the second main electrode extends on the interlayer insulating film in a direction parallel to the surface of the second semiconductor layer so as to reach above the second semiconductor layer beyond an outer periphery of the third semiconductor layer.

16. The device according to claim 15, further comprising:
a plurality of guard ring layers of the second conductivity type extending from the surface of the second semiconductor layer into the second semiconductor layer and having an upper end connected to the interlayer insulating film.
